(19) United States
(12) Patent Application Publication
(10) Pub. No.: US 2019/0243201 A1
(43) Pub. Date: Aug. 8, 2019

(54) DISPLAY PANEL AND DISPLAY DEVICE

(71) Applicants: HKC Corporation Limited, Shenzhen (CN); Chongqing HKC Optoelectronics Technology Co., ltd., Chongqing (CN)

(72) Inventor: Zeyao LI, Chongqing (CN)

(21) Appl. No.: 16/339,372

(22) PCT Filed: May 17, 2018
(86) PCT No.: PCT/CN2018/087200

§ 371 Date: Apr. 4, 2019

(30) Foreign Application Priority Data
Jun. 20, 2017 (CN) 201710470473.1

(51) Int. Cl. G02F 1/1362; G02F 1/133; G02F 1/1345; H01L 27/12

(52) U.S. Cl. CPC G02F 1/136286; G02F 1/13306; G02F 2001/136295; H01L 27/124; H01L 27/1259; G02F 1/13452

(57) ABSTRACT

The present application discloses a display panel and a display device. The display panel includes: a substrate; an active switch formed on the substrate; a plurality of data lines formed on the substrate and coupled to the active switch; a plurality of scan lines formed on the substrate and coupled to the active switch; the scan lines and the data lines are vertically intersected with each other to form a plurality of pixel regions; the scan lines include at least two metal layers; an insulating layer is provided between two adjacent metal layers; and different metal layers are capacitively coupled to each other.

### TECHNICAL FIELD

The present application relates to the technical field of display, and in particular, to a display panel and a display device.

### BACKGROUND

A display device has many advantages such as thin body, power-saving, and no radiation, and thus has been widely used. Most display devices currently available on the market are backlight display devices, which include a Liquid Crystal Display (LCD) panel and a backlight module. The working principle of the LCD panel is to place liquid crystal molecules in two parallel substrates, and apply driving voltages on the two substrates to control the rotation direction of the liquid crystal molecules to refract the light of the backlight module to generate a picture.

Thin Film Transistor-Liquid Crystal Display (TFT-LCD) has gradually become a leading role in the display field due to its low power consumption, excellent picture quality, and higher production yield. Similarly, the TFT-LCD includes an LCD panel and a backlight module. The LCD panel includes a Color Film Substrate (CF Substrate) (also called a color filter substrate) and a Thin Film Transistor Substrate (TFT Substrate), and transparent electrodes are disposed on opposite sides of the substrates. A Liquid Crystal (LC) molecule layer is sandwiched between the two substrates. The existing LCD panel generally has a CF substrate in front (here, “the front” is defined herein as the gaze of a human eye 20) and the TFT substrate at the rear, and the CF substrate 11 has a BM (black matrix) layer, also called a light-shielding layer for preventing background light leakage and improving the display contrast.

The TFT-LCD is one of the main varieties of the current flat panel display, and has become an important display platform in modern IT and video products. The main driving principle of the TFT-LCD is; a system mainboard connects an R/G/B tri-color compression signal, a control signal and power to a connector on a Printed Circuit Board (PCB board) through a wire, and data is processed by a Timing Controller (TCON) IC on the PCB board, passes through the PCB board, and is connected to a display region through a Source-Chip on Film (S-COF) and a Gate-Chip on Film (G-COF), so that the LCD obtains the required power and signal.

The core component in the LCD is a Thin-Film Transistor array (TFT), and for a single TFT, there are mainly two signal inputs, i.e., a data signal and a gate drive signal. The gate drive signal acts to turn the TFT on and off, which plays a crucial role in accurately inputting a data signal into the Pixel over time.

As the resolution of the LCD becomes higher and higher, the loading on a scan line in the display region is also larger and larger, and the increase of the loading causes the RC delay of a gate drive signal in the transmission process is also getting worse.

### SUMMARY

The technical problem to be solved by the present application is to provide a display panel capable of reducing signal transmission delay of a scan line.

In addition, the present application also provides a display device including the foregoing display panel.

The objective of the present application is implemented by means of the following technical solution.

The present invention discloses a display panel, including:

a substrate:

an active switch formed on the substrate;

a plurality of data lines formed on the substrate and coupled to the active switch;

a plurality of scan lines formed on the substrate and coupled to the active switch, the scan lines and the data lines being arranged vertically to form a plurality of pixel regions; and

a gate drive circuit coupled to the plurality of scan lines;

where the scan line includes at least two metal layers; an insulating layer is provided between two adjacent metal layers; different metal layers are capacitively coupled to each other; the scan line includes a first metal layer and a second metal layer; the insulating layer is provided between the first metal layer and the second metal layer; the first metal layer and the second metal layer adopt the same material; the active switch includes a gate; the first metal layer and the second metal layer are coupled to the gate, separately; the gate includes a first gate metal layer and a second gate metal layer; the first metal layer is coupled to the first gate metal layer; the second metal layer is coupled to the second gate metal layer; the first metal layer is coupled to a first pin of the gate drive circuit; and the second metal layer is coupled to a second pin of the gate drive circuit.

The present invention further discloses a display panel, including:

a substrate;

an active switch formed on the substrate;

a plurality of data lines formed on the substrate and coupled to the active switch; and

a plurality of scan lines formed on the substrate and coupled to the active switch, the scan lines and the data lines being arranged vertically to form a plurality of pixel regions:

the scan line includes at least two metal layers; an insulating layer is provided between two adjacent metal layers; and different metal layers are capacitively coupled to each other.

Optionally, the scan line includes a first metal layer and a second metal layer.

Optionally, the insulating layer is provided between the first metal layer and the second metal layer, and the material adopted by the insulating layer is silicon nitride or silicon oxide.

Optionally, the first metal layer and the second metal layer may adopt the same material.

Optionally, the active switch includes a gate; the first metal layer and the second metal layer are coupled to the gate, separately; and the gate is merely a single metal layer.

Optionally, the active switch includes a gate; the first metal layer and the second metal layer are coupled to the gate, separately; the gate includes a first gate metal layer and a second gate metal layer; the first metal layer is coupled to the first gate metal layer; and the second metal layer is coupled to the second gate metal layer.

Optionally, the display panel further includes a gate drive circuit; and the first metal layer is coupled to a first pin of the gate drive circuit, and the second metal layer is coupled to a second pin of the gate drive circuit.

Optionally, the display panel further includes a gate drive circuit; and the first metal layer and the second metal layer are coupled to the same pin of the gate drive circuit.

The present invention further discloses a display device, including a control circuit and a display panel, the display panel including:

a substrate:

an active switch formed on the substrate;

a plurality of data lines formed on the substrate and coupled to the active switch; and

a plurality of scan lines formed on the substrate and coupled to the active switch, the scan lines and the data lines being arranged vertically to form a plurality of pixel regions;

the scan line includes at least two metal layers; an insulating layer is provided between two adjacent metal layers; and different metal layers are capacitively coupled to each other.

Optionally, the scan line includes a first metal layer and a second metal layer.

Optionally, the insulating layer is provided between the first metal layer and the second metal layer, and the material adopted by the insulating layer is silicon nitride or silicon oxide.

Optionally, the first metal layer and the second metal layer may adopt the same material.

Optionally, the active switch includes a gate; the first metal layer and the second metal layer are coupled to the gate, separately, and the gate is merely a single metal layer.

Optionally, the active switch includes a gate; the first metal layer and the second metal layer are coupled to the gate, separately; the gate includes a first gate metal layer and a second gate metal layer; the first metal layer is coupled to the first gate metal layer; and the second metal layer is coupled to the second gate metal layer.

Optionally, the display panel further includes a gate drive circuit; the first metal layer is coupled to a first pin of the gate drive circuit, and the second metal layer is coupled to a second pin of the gate drive circuit.

Optionally, the display panel further includes a gate drive circuit; and the first metal layer and the second metal layer are coupled to the same pin of the gate drive circuit.

Optionally, the scan line includes a first metal layer and a second metal layer; the insulating layer is provided between the first metal layer and the second metal layer, and the material adopted by the insulating layer is silicon nitride or silicon oxide.

Optionally, the scan line includes a first metal layer and a second metal layer; and the first metal layer and the second metal layer may adopt the same material.

Optionally, the scan line includes at least two metal layers; an insulating layer is provided between two adjacent metal layers; different metal layers are capacitively coupled to each other; the scan line includes a first metal layer and a second metal layer; the insulating layer is provided between the first metal layer and the second metal layer; the first metal layer and the second metal layer adopt the same material; the active switch includes a gate; the first metal layer and the second metal layer are coupled to the gate, separately; the gate includes a first gate metal layer and a second gate metal layer; the first metal layer is coupled to the first gate metal layer; the second metal layer is coupled to the second gate metal layer; the first metal layer is coupled to a first pin of the gate drive circuit; and the second metal layer is coupled to a second pin of the gate drive circuit.

The traditional gate insulating layer adopts a silicon dioxide film; such insulating layer has poor ability of blocking diffusion of foreign particles, and the stability performance of the active switch is greatly reduced. However, in addition to excellent electrical properties, a silicon nitride or silicon oxide film has a large dielectric constant and a stronger ability of blocking sodium ion diffusion and water vapor permeation as well as diffusion of other impurity particles.

The scan line of the present application at least includes two metal layers, and different metal layers are capacitively coupled to each other. By means of the capacitive coupling effect among the metal layers, the loading pressure of the scan line is reduced, so that the delay in capacitance and resistance is reduced in the process that the scan line transmits the signal, and thus the scan line can accurately transmit the signal to a pixel electrode.

### BRIEF DESCRIPTION OF DRAWINGS

The drawings are included to provide further understanding of embodiments of the present application, which constitute a part of the specification and illustrate the embodiments of the present application, and describe the principles of the present application together with the text description. Apparently, the accompanying drawings in the following description show merely some embodiments of the present application, and a person of ordinary skill in the art may still derive other accompanying drawings from these accompanying drawings without creative efforts. In the accompanying drawings:

FIG. 1 is a structural schematic diagram of a display panel according to an embodiment of the present application;

FIG. 2 is a schematic diagram of a display panel and gate drive according to an embodiment of the present application;

FIG. 3 is another schematic diagram of the display panel and gate drive according to an embodiment of the present application;

FIG. 4 is a schematic top view of the display panel according to an embodiment of the present application;

FIG. 5 is a schematic flowchart of a method for manufacturing a display panel according to an embodiment of the present application;

FIG. 6 is another schematic flowchart of the method for manufacturing a display panel according to an embodiment of the present application; and

FIG. 7 is a structural schematic diagram of a display device according to an embodiment of the present application.

### DETAILED DESCRIPTION

The specific structure and function details disclosed herein are merely representative, and are intended to describe exemplary embodiments of the present application. However, the present application can be specifically embodied in many alternative forms, and should not be interpreted to be limited to the embodiments described herein.

In the description of the present application, it should be understood that, orientation or position relationships indicated by the terms “center”, “transversal”, “upper”, “lower”, “left”, “right”, “vertical”, “horizontal”, “top”, “bottom”, “inner”, “outer”, etc. are based on the orientation or position relationships as shown in the drawings, for ease of the description of the present application and simplifying the description only, rather than indicating or implying that the indicated device or element must have a particular orientation or be constructed and operated in a particular orientation. Therefore, these terms should not be understood as a limitation to the present application. In addition, the terms “first”, “second” are merely for a descriptive purpose, and cannot to be understood to indicate or imply a relative importance, or implicitly indicate the number of the indicated technical features. Hence, the features defined by “first”, “second” can explicitly or implicitly include one or more of the features. In the description of the present application, “a plurality of” means two or more, unless otherwise stated. In addition, the term “include” and any variations thereof are intended to cover a non-exclusive inclusion.

In the description of the present application, it should be understood that, unless otherwise specified and defined, the terms “install”, “connected with”, “connected to” should be comprehended in a broad sense. For example, these terms may be comprehended as being fixedly connected, detachably connected or integrally connected; mechanically connected or coupled; or directly connected or indirectly connected through an intermediate medium, or in an internal communication between two elements. The specific meanings about the foregoing terms in the present application may be understood for those skilled in the art according to specific circumstances.

The terms used herein are merely for the purpose of describing the specific embodiments, and are not intended to limit the exemplary embodiments. As used herein, the singular forms “a”, “an” are intended to include the plural forms as well, unless otherwise indicated in the context clearly. It will be further understood that the terms “comprise” and/or “include” used herein specify the presence of the stated features, integers, steps, operations, elements and/or components, but do not preclude the presence or addition of one or more other features, integers, steps, operations, elements, components and/or combinations thereof.

The present application is further described in details below with reference to the drawings and the preferred embodiments.

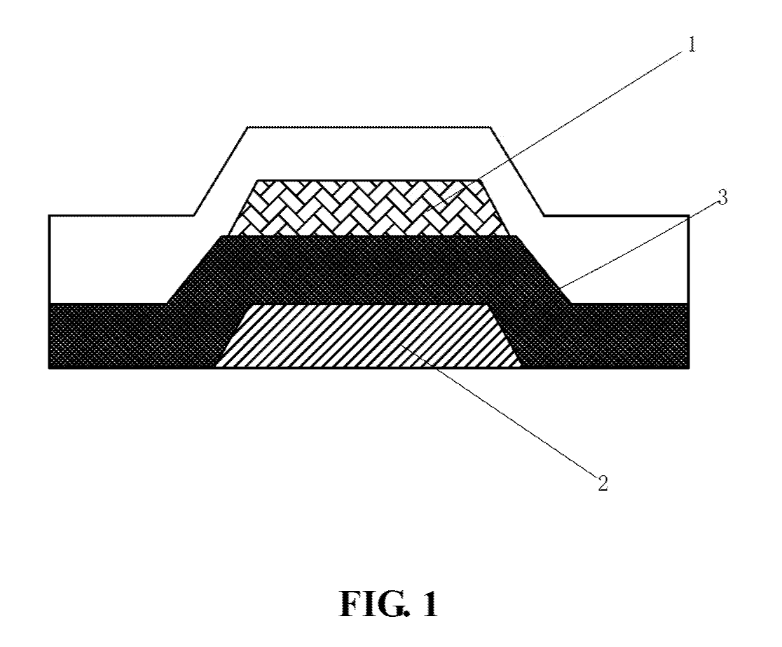

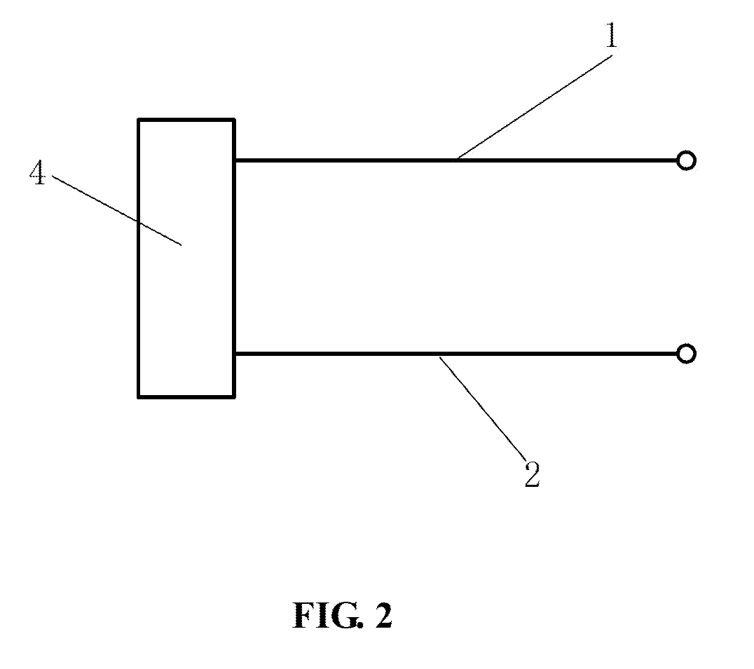

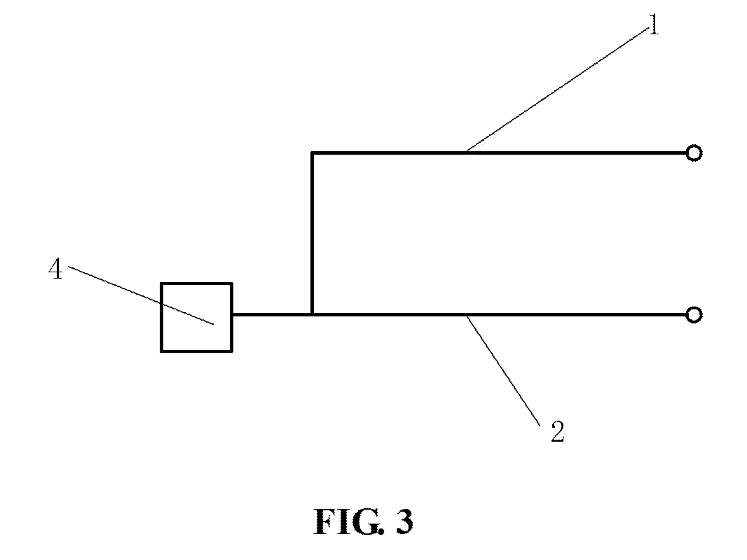

As shown in FIGS. 1-3, this embodiment discloses a display panel, including:

a substrate;

an active switch formed on the substrate;

a plurality of data lines formed on the substrate and coupled to the active switch; and

a plurality of scan lines formed on the substrate and coupled to the active switch, the scan lines and the data lines being arranged vertically to form a plurality of pixel regions;

the scan line includes at least two metal layers; an insulating layer is provided between two adjacent metal layers; and different metal layers are capacitively coupled to each other.

It should be noted that the scan line in this embodiment may include two metal layers, three metal layers or multiple metal layers, and is not limited to the specific number of layers listed in this embodiment.

The scan line at least includes two metal layers, and different metal layers are capacitively coupled to each other. By means of the capacitive coupling effect among the metal layers, the loading pressure of the scan line is reduced, so that the delay in capacitance and resistance is reduced in the process that the scan line transmits the signal, and thus the scan line can accurately transmit the signal to the active switch.

As a further improvement of this embodiment, the scan line includes a first metal layer 1 and a second metal layer 2 which are capacitively coupled.

In the case that the scan line only has one layer, if the resolution is increased, since the scan line only has one layer, the loading of the scan line is larger and larger, which will cause the delay in capacitance and resistance is also getting worse in the process that the scan line transmits a gate drive signal. As a result, the transmission of the gate drive signal cannot be accurately turned on or off as originally thought, resulting in that the expected effect cannot be achieved when transmitting an input signal to the pixel electrode, thus failing to achieve the expected display effect. Therefore, by capacitively coupling the first metal layer 1 to the second metal layer 2, the coupling capacitance would be produced between the first metal layer 1 and the second metal layer 2; and by means of the capacitive coupling effect among the metal layers, the loading pressure of the scan line is reduced, so that the delay in capacitance and resistance is reduced in the process that the scan line transmits the signal, and thus the scan line can accurately transmit the signal to a pixel electrode to achieve a better display effect.

As a further improvement of this embodiment, the display panel includes: a substrate; a plurality of data lines formed on the substrate; and a plurality of scan lines formed on the substrate; the scan lines and the data lines are arranged vertically to form a plurality of pixel regions; the scan line includes a first metal layer 1 and a second metal layer 2; an insulating layer 3 is provided between the first metal layer 1 and the second metal layer 2; and the first metal layer 1 and the second metal layer 2 are capacitively coupled.

An insulating layer 3 is provided between the first metal layer 1 and the second metal layer 2, so that the diffusion of foreign particles can be blocked, and the stability performance of the active switch is improved.

As a further improvement of this embodiment, the display panel includes: a substrate; a plurality of data lines formed on the substrate; and a plurality of scan lines formed on the substrate; the scan lines and the data lines are arranged vertically to form a plurality of pixel regions; the scan line includes a first metal layer 1 and a second metal layer 2; the first metal layer 1 and the second metal layer 2 are capacitively coupled; and the first metal layer 1 and the second metal layer 2 may adopt the same material.

The first metal layer 1 and the second metal layer 2 may adopt the same material, and thus the capacitive coupling effect between the first metal layer 1 and the second metal layer 2 is better, and the loading pressure of the scan line can be reduced better, so that the delay in capacitance and resistance is reduced in the process that the scan line transmits the signal, and thus the scan line can accurately transmit the signal to the pixel electrode to achieve a better display effect.

As a further improvement of this embodiment, the display panel includes the display panel includes: a substrate; and a plurality of scan lines and scan lines formed on the substrates; the scan lines and the data lines are arranged vertically to form a plurality of pixel regions; the active switch includes a gate; the gate is provided on the substrate; an insulating layer is provided on the gate; a semiconductor layer is provided on the insulating layer corresponding to the gate; both ends of the semiconductor layer are provided with a source and a drain of the separated active switch; a channel is formed between the source and the drain; and the bottom of the channel is the semiconductor layer. The scan line includes a first metal layer 1 and a second metal layer 2; the first metal layer 1 and the second metal layer 2 are coupled to the gate, separately; and the gate is merely a single metal layer.

As a further improvement of this embodiment, the display panel includes the display panel includes: a substrate; a plurality of scan lines and scan lines formed on the substrates; the scan lines and the data lines are arranged vertically to form a plurality of pixel regions; and an active switch. The active switch includes a gate; the gate is provided on the substrate; an insulating layer is provided on the gate; a semiconductor layer is provided on the insulating layer corresponding to the gate; both ends of the semiconductor layer are provided with a source and a drain of the separated active switch; a channel is formed between the source and the drain; and the bottom of the channel is the semiconductor layer. The scan line includes a first metal layer 1 and a second metal layer 2; the first metal layer 1 and the second metal layer 2 are coupled to the gate, separately; the gate includes a first gate metal layer and a second gate metal layer; the first metal layer 1 is coupled to the first gate metal layer; and the second metal layer 2 is coupled to the second gate metal layer.

As a further improvement of this embodiment, the display panel includes the display panel includes: a substrate; and a plurality of scan lines and scan lines formed on the substrates; the scan lines and the data lines are arranged vertically to form a plurality of pixel regions. The display panel further includes a gate drive circuit 4; the first metal layer 1 is coupled to a first pin of the gate drive circuit 4, and the second metal layer 2 is coupled to a second pin of the gate drive circuit 4.

The first metal layer 1 is directly connected to the first pin, and the second metal layer 2 is directly connected to the second pin. In this way, during production and manufacture, the production process is simpler.

As a further improvement of this embodiment, the display panel includes the display panel includes: a substrate; and a plurality of scan lines and scan lines formed on the substrates; the scan lines and the data lines are arranged vertically to form a plurality of pixel regions. The display panel further includes a gate drive circuit 4. The first metal layer 1 and the second metal layer 2 are coupled to the same pin of the gate drive circuit 4.

The first metal layer 1 and the second metal layer 2 are coupled to the same pin, and thus when the signal is transmitted to the first metal layer 1 and the second metal layer 2, the signal can also be input to the first metal layer 1 and the second metal layer 2 simultaneously, so as to achieve the capacitive coupling effect.

As a further improvement of this embodiment, the display panel includes: a substrate; and a plurality of scan lines and scan lines formed on the substrates; the scan lines and the data lines are arranged vertically to form a plurality of pixel regions; the scan line includes a first metal layer 1 and a second metal layer 2; the first metal layer 1 and the second metal layer 2 of the scan line are disposed in parallel; an insulating layer 3 is provided between the first metal layer 1 and the second metal layer 2; and the insulating layer 3 adopts silicon nitride or silicon oxide. The display panel firther includes an active switch; the active switch includes a gate; the gate is provided on the substrate; an insulating layer is provided on the gate; a semiconductor layer is provided on the insulating layer corresponding to the gate; both ends of the semiconductor layer are provided with a source and a drain of the separated active switch; a channel is formed between the source and the drain; and the bottom of the channel is the semiconductor layer. The first metal layer 1 and the second metal layer 2 are coupled to the gate, separately; the gate includes a first gate metal layer and a second gate metal layer; the first metal layer 1 is coupled to the first gate metal layer; and the second metal layer 2 is coupled to the second gate metal layer.

By means of the capacitive coupling effect among the metal layers, the loading pressure of the scan line is reduced, so that the delay in capacitance and resistance is reduced in the process that the scan line transmits the signal, and thus the scan line can accurately transmit the signal to a pixel electrode. However, the traditional gate insulating layer 3 adopts a silicon dioxide film, such insulating layer 3 has poor ability of blocking the diffusion of foreign particles, and thus the stability performance of the active switch is greatly reduced. However, in addition to excellent electrical properties, a silicon nitride or silicon oxide film has a large dielectric constant and a stronger ability of blocking sodium ion diffusion and water vapor permeation as well as diffusion of other impurity particles.

Specifically, the metal layers in the foregoing embodiment are partially overlapped, and the overlapped parts are coupled through a via hole.

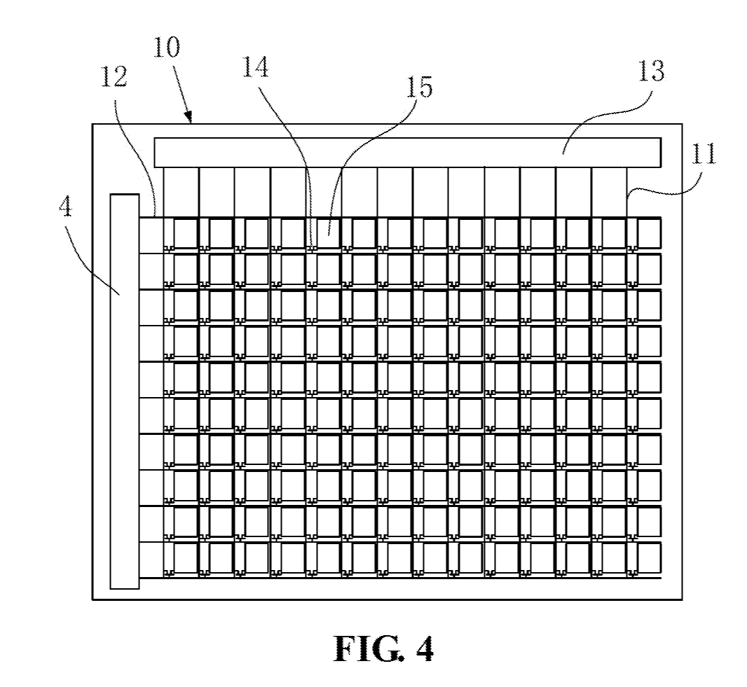

With reference to FIG. 4, a data drive circuit 13 and a gate drive circuit 4 are bonded at the edge of the substrate 10; a display region of the substrate 10 is provided with scan lines 12 provided horizontally and data lines 11 provided vertically; the active switch 14 is coupled to the data line 11 and the scan line 12, separately; a rectangular regions formed by sequentially intersecting the plurality of data lines with the plurality of scan lines is provided with a plurality of pixels 15; the pixels 15 are electrically connected to the active switch 14.

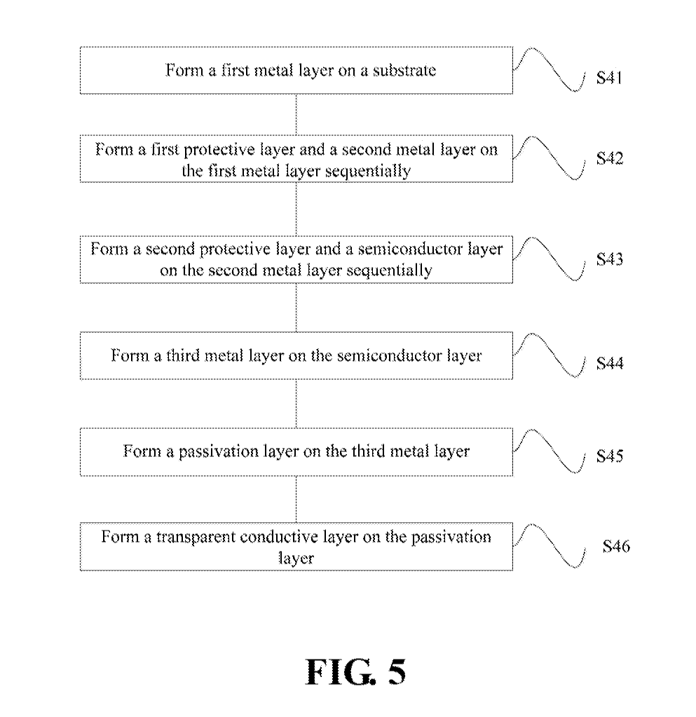

With reference to FIG. 5, this embodiment discloses a method for manufacturing a display panel, including:

S41: Form a first metal layer on a substrate.

S42: Form a first protective layer and a second metal layer on the first metal layer sequentially.

S43: Form a second protective layer and a semiconductor layer on the second metal layer sequentially.

S44: Form a third metal layer on the semiconductor layer.

S45: Form a passivation layer on the third metal layer. 1′

S46: forming a transparent conductive layer on the passivation layer.

The foregoing six processes represent six photomask manufacturing processes. The specific contents of the six photomask manufacturing processes are further described below.

An optional photomask manufacturing process: cleaning a substrate; sputtering a first metal material layer on the cleaned substrate; performing pre-film cleaning after the first metal material layer is sputtered; then coating the cleaned first metal material layer with a photoresist; aligning and exposing the photoresist by a first photomask; developing the first metal material layer with a developing liquid to obtain the pattern of a first metal layer; then etching the first metal material layer with an etching liquid to obtain the first metal layer; and removing the residual photoresist.

An optional photomask manufacturing process: cleaning a substrate; depositing a first protective layer on a first metal layer through chemical vapor deposition technology; then sputtering a second metal material layer on the first protective layer; performing pre-film cleaning after the second metal material layer is sputtered; then coating the cleaned second metal material layer with a photoresist; aligning and exposing the photoresist by a second photomask; developing the second metal material layer with a developing liquid to obtain the pattern of a second metal layer; then etching the second metal material layer with an etching liquid to obtain the second metal layer; and removing the residual photoresist.

An optional photomask manufacturing process: cleaning a substrate; depositing a second protective layer on a second metal layer through chemical vapor deposition technology; then sputtering a semiconductor material layer on the second protective layer; performing pre-film cleaning after the semiconductor material layer is sputtered; then coating the cleaned semiconductor material layer with a photoresist; aligning and exposing the photoresist by a third photomask; developing the semiconductor material layer with a developing liquid to obtain the pattern of a semiconductor layer; then etching the semiconductor material layer with an etching liquid to obtain the semiconductor layer; and removing the residual photoresist.

An optional photomask manufacturing process: cleaning a substrate; forming a third metal material layer on the cleaned semiconductor layer; performing pre-film cleaning after the third metal material layer is sputtered; then coating the cleaned third metal material layer with a photoresist; aligning and exposing the photoresist by a fourth photomask; developing the third metal material layer with a developing liquid to obtain the pattern of a third metal layer; then etching the third metal material layer with an etching liquid to obtain the third metal layer, i.e., the source and the drain of the active switch; and removing the residual photoresist.

An optional photomask manufacturing process: cleaning a substrate; fonring a third protective material layer on the cleaned third metal layer; then coating the third metal material layer with a photoresist; aligning and exposing the photoresist by a fifth photomask; developing the third protective material layer with a developing liquid to obtain the pattern of a passivation layer; then etching the third protective material layer with an etching liquid to obtain the passivation layer; and removing the residual photoresist.

An optional photomask manufacturing process: cleaning a substrate; forming a transparent electrode material layer on the cleaned passivation layer; then coating the transparent electrode material layer with a photoresist; aligning and exposing the photoresist by a sixth photomask; developing the transparent electrode material layer with a developing liquid to obtain the pattern of a transparent electrode layer; then etching the transparent electrode material layer with an etching liquid to obtain the transparent electrode layer, and removing the residual photoresist.

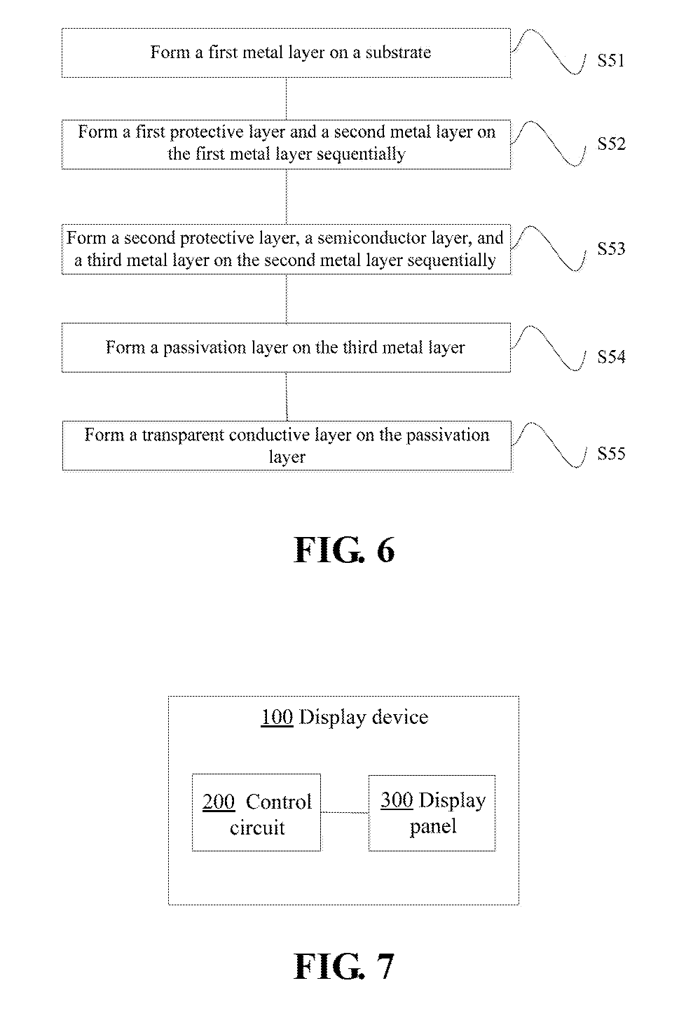

With reference to FIG. 6, this embodiment discloses a method for manufacturing a display panel, including:

S51: Form a first metal layer on a substrate.

S52: Form a first protective layer and a second metal layer on the first metal layer sequentially.

S53: Form a second protective layer, a semiconductor layer, and a third metal layer on the second metal layer sequentially.

S54: Form a passivation layer on the third metal layer.

S55: Form a transparent conductive layer on the passivation layer.

The foregoing five processes represent five photomask manufacturing processes. The specific contents of the five photomask manufacturing processes are further described below.

An optional photomask manufacturing process: first cleaning a substrate; sputtering a first metal material layer on the cleaned substrate; performing pre-film cleaning after the first metal material layer is sputtered; then coating the cleaned first metal material layer with a photoresist; aligning and exposing the photoresist by a first photomask; developing the first metal material layer with a developing liquid to obtain the pattern of a first metal layer; then etching the first metal material layer with an etching liquid to obtain the first metal layer; and removing the residual photoresist.

An optional photomask manufacturing process: cleaning a substrate; depositing a first protective layer on a first metal layer through chemical vapor deposition technology; then sputtering a second metal material layer on the first protective layer; performing pre-film cleaning after the second metal material layer is sputtered; then coating the cleaned second metal material layer with a photoresist; aligning and exposing the photoresist by a second photomask; developing the second metal material layer with a developing liquid to obtain the pattern of a second metal layer; then etching the second metal material layer with an etching liquid to obtain the second metal layer; and removing the residual photoresist.

An optional photomask manufacturing process: cleaning a substrate; and sequentially sputtering a second protective material layer, a semiconductor material layer and a third metal material layer on a second metal layer through chemical vapor deposition technology; performing pre-film cleaning after sputtering; then coating the cleaned third metal material layer with a photoresist; aligning and exposing the photoresist by a third photomask; developing the third metal material layer with a developing liquid to obtain the pattern of a third metal layer; then etching the third metal material layer with an etching liquid to obtain the third metal layer; and removing the residual photoresist.

An optional photomask manufacturing process: cleaning a substrate; forming a third protective material layer on the cleaned third metal layer; then coating the third metal material layer with a photoresist; aligning and exposing the photoresist by a fifth photomask; developing the third protective material layer with a developing liquid to obtain the pattern of a passivation layer; then etching the third protective material layer with an etching liquid to obtain the passivation layer; and removing the residual photoresist.

An optional photomask manufacturing process: cleaning a substrate; forming a transparent electrode material layer on the cleaned passivation layer; then coating the transparent electrode material layer with a photoresist; aligning and exposing the photoresist by a sixth photomask; developing the transparent electrode material layer with a developing liquid to obtain the pattern of a transparent electrode layer; then etching the transparent electrode material layer with an etching liquid to obtain the transparent electrode layer; and removing the residual photoresist.

The display panel according to the embodiments of the present application may be any one of the following: a Twisted Nematic (TN) display panel, a Super Twisted Nematic (STN) display panel, an In-Plane Switching (IPS) display panel, a Vertical Alignment (VA) display panel, an LCD display panel, an OLED panel, a QLED panel, a curved-surface display panel, or other display panels. The active switch of the present application includes a TFT.

As shown in FIG. 7, in an embodiment of the present application, this embodiment discloses a display device 100, which includes a control circuit board 200 and a display panel 300, where the specific structure and connection relationships of the display device 100 in this embodiment can refer to the display panel 300 in the foregoing embodiments and FIGS. 1-3, and the display device is not described in details here. The display device according to the embodiment of the present application may be an LCD device, a QLED display device, an OLED display device or other display device. When the display device according to the embodiment of the present application is an LCD device, the LCD device includes a backlight module, which may be used as a light source for supplying sufficient brightness and uniformly distributed light. The backlight module of this embodiment may be front-light or backlight. It should be noted that the backlight module of this embodiment is not limited thereto.

The contents above are further detailed descriptions of the present application in conjunction with specific embodiments, and the specific implementation of the present application is not limited to these descriptions. It will be apparent to those skilled in the art that various simple deductions or substitutions may be made without departing from the spirit of the present application, and should be considered to be within the scope of protection of the present application.

1. A display panel, comprising:
a substrate;
an active switch formed on the substrate;
a plurality of data lines formed on the substrate and coupled to the active switch;
a plurality of scan lines formed on the substrate and coupled to the active switch, the scan lines and the data lines being vertically intersected with each other to form a plurality of pixel regions; and
a gate drive circuit coupled to the plurality of scan lines;
wherein the scan line comprises at least two metal layers; an insulating layer is provided between two adjacent metal layers; different metal layers are capacitively coupled to each other, the scan line comprises a first metal layer and a second metal layer; the insulating layer is provided between the first metal layer and the second metal layer, the first metal layer and the second metal layer adopt the same material; the active switch comprises a gate; the first metal layer and the second metal layer are coupled to the gate, separately, the gate comprises a first gate metal layer and a second gate metal layer; the first metal layer is coupled to the first gate metal layer, the second metal layer is coupled to the second gate metal layer, the first metal layer is coupled to a first pin of the gate drive circuit; and the second metal layer is coupled to a second pin of the gate drive circuit.

2. A display panel, comprising:
a substrate;
an active switch formed on the substrate;
a plurality of data lines formed on the substrate and coupled to the active switch; and
a plurality of scan lines formed on the substrate and coupled to the active switch, the scan lines and the data lines being vertically intersected with each other to form a plurality of pixel regions;
the scan line comprises at least two metal layers; an insulating layer is provided between two adjacent metal layers; and different metal layers are capacitively coupled to each other.

3. The display panel according to claim 1, wherein the scan line comprises a first metal layer and a second metal layer.

4. The display panel according to claim 3, wherein the insulating layer is provided between the first metal layer and the second metal layer, and the material adopted by the insulating layer is silicon nitride or silicon oxide.

5. The display panel according to claim 3, wherein the first metal layer and the second metal layer may adopt the same material.

6. The display panel according to claim 3, wherein the active switch comprises a gate; the first metal layer and the second metal layer are coupled to the gate, separately; and the gate is merely a single metal layer.

7. The display panel according to claim 3, wherein the active switch comprises a gate; the first metal layer and the second metal layer are coupled to the gate, separately; the gate comprises a first gate metal layer and a second gate metal layer; the first metal layer is coupled to the first gate metal layer; and the second metal layer is coupled to the second gate metal layer.

8. The display panel according to claim 3, further comprising a gate drive circuit, wherein the first metal layer is coupled to a first pin of the gate drive circuit, and the second metal layer is coupled to a second pin of the gate drive circuit.

9. The display panel according to claim 3, further comprising a gate drive circuit, wherein the first metal layer and the second metal layer are coupled to the same pin of the gate drive circuit.

10. A display device, comprising a control circuit and a display panel, the display panel comprising:
a substrate;
an active switch formed on the substrate;
a plurality of data lines formed on the substrate and coupled to the active switch; and
a plurality of scan lines formed on the substrate and coupled to the active switch, the scan lines and the data lines being vertically intersected with each other to form a plurality of pixel regions;
the scan line comprises at least two metal layers; an insulating layer is provided between two adjacent metal layers; and different metal layers are capacitively coupled to each other.

11. The display device according to claim 10, wherein the scan line comprises a first metal layer and a second metal layer.

12. The display device according to claim 11, wherein the insulating layer is provided between the first metal layer and the second metal layer, and the material adopted by the insulating layer is silicon nitride or silicon oxide.

13. The display device according to claim 11, wherein the first metal layer and the second metal layer may adopt the same material.

14. The display device according to claim 11, wherein the active switch comprises a gate; the first metal layer and the second metal layer are coupled to the gate, separately; and the gate is merely a single metal layer.

15. The display device according to claim 11, wherein the active switch comprises a gate; the first metal layer and the second metal layer are coupled to the gate, separately; the gate comprises a first gate metal layer and a second gate metal layer; the first metal layer is coupled to the first gate metal layer; and the second metal layer is coupled to the second gate metal layer.

16. The display device according to claim 11, wherein the display panel further comprises a gate drive circuit; the first metal layer is coupled to a first pin of the gate drive circuit, and the second metal layer is coupled to a second pin of the gate drive circuit.

17. The display device according to claim 11, wherein the display panel further comprises a gate drive circuit; and the first metal layer and the second metal layer are coupled to the same pin of the gate drive circuit.

18. The display device according to claim 10, wherein the scan line comprises a first metal layer and a second metal layer; the insulating layer is provided between the first metal layer and the second metal layer, and the material adopted by the insulating layer is silicon nitride or silicon oxide.

19. The display device according to claim 10, wherein the scan line comprises a first metal layer and a second metal layer, and the first metal layer and the second metal layer may adopt the same material.

20. The display device according to claim 10, wherein the scan line comprises at least two metal layers; an insulating layer is provided between two adjacent metal layers; different metal layers are capacitively coupled to each other; the scan line comprises a first metal layer and a second metal layer; the insulating layer is provided between the first metal layer and the second metal layer; the first metal layer and the second metal layer adopt the same material; the active switch comprises a gate; the first metal layer and the second metal layer are coupled to the gate, separately, the gate comprises a first gate metal layer and a second gate metal layer; the first metal layer is coupled to the first gate metal layer; the second metal layer is coupled to the second gate metal layer; the first metal layer is coupled to a first pin of the gate drive circuit; and the second metal layer is coupled to a second pin of the gate drive circuit.
